(19) United States
(12) Patent Application Publication
(10) Pub. No.: US 2016/0260479 A1
(43) Pub. Date: Sep. 8, 2016

(54) SEMICONDUCTOR MEMORY DEVICE AND METHOD OF MANUFACTURING THE SAME

(71) Applicant: KABUSHIKI KAISHA TOSHIBA, Minato-ku (JP)

(72) Inventors: Hiroyuiki ODE, Yokkaichi (JP); Takeshi YAMAGUCHI, Yokkaichi (JP); Takeshi TAKAGI, Yokkaichi (JP); Toshiharu TANAKA, Yokkaichi (JP); Masaki YAMATO, Yokkaichi (JP)

(73) Assignee: KABUSHIKI KAISHA TOSHIBA, Minato-ku (JP)

(21) Appl. No.: 14/844,424

(22) Filed: Sep. 3, 2015

Related U.S. Application Data
(60) Provisional application No. 62/126,903, filed on Mar. 2, 2015.

(51) Int. Cl. G11C 13/00; H01L 45/00

(52) U.S. Cl. CPC G11C 13/0007; G11C 13/0021; H01L 45/1616; H01L 45/146

(57) ABSTRACT

A semiconductor memory device comprises: a memory cell array 11; and a control circuit 16 that controls a voltage applied to the memory cell array 11. The memory cell array 11 includes: a plurality of word lines WL and bit lines BL that intersect each other; and a memory cell MC disposed at each of intersections of these word lines WL and bit lines BL. The memory cell MC includes a variable resistance element VR and a non-ohmic element NO. The variable resistance element VR is formed by a hafnium oxide crystalline film of monoclinic crystal in which a proportion of a component oriented in a (−1, 1, 1) plane and a (1, 1, 1) plane is 90% or more. This hafnium oxide crystalline film can be manufactured by a film-forming process by atomic layer deposition, employing an inorganic type hafnium precursor.

### CROSS-REFERENCE TO RELATED APPLICATIONS

This application is based upon and claims the benefit of priority from the prior U.S. Provisional Application 62/126,903, filed on Mar. 2, 2015, the entire contents of which are incorporated herein by reference.

### BACKGROUND

1. Field

Embodiments described herein relate to a semiconductor memory device and a method of manufacturing the same.

2. Description of the Related Art

In recent years, ReRAM (resistance varying type memory: Resistive RAM) that utilizes as memory a variable resistance element whose resistance value is reversibly varied, has been proposed, and increases in capacity and higher degrees of integration have been proceeding. A switching operation at a low current is required to achieve a large capacity ReRAM device. In a low current operation of ReRAM, it is required to suppress variation of current due to noise, and improve reliability of data retention characteristics, endurance, and so on.

### BRIEF DESCRIPTION OF THE DRAWINGS

FIG. 1 is an example of a block diagram of a semiconductor memory device according to a first embodiment.

FIG. 2 is a perspective view of part of a memory cell array 11.

FIG. 3 is a cross-sectional view, taken along the I-I′ line in FIG. 2 and viewed in the direction of the arrows, of a single memory cell portion.

FIG. 4 is a graph showing a relationship between deposition temperature and crystalline structure in an ALD film-forming process of hafnium oxide (HfO₂).

FIG. 5 is a graph showing a relationship between crystalline structure and current characteristics of hafnium oxide (HfO₂) employed in a variable resistance element.

FIG. 6 is an example of a circuit diagram of a memory cell array 11 according to a second embodiment.

FIG. 7 is an example of a perspective view showing a stacked structure of the memory cell array 11.

### DETAILED DESCRIPTION

A semiconductor memory device according to an embodiment includes: a memory cell array; and a control circuit that controls a voltage applied to the memory cell array. The memory cell array includes: a first wiring line; a second wiring line intersecting the first wiring line; and a memory cell disposed at an intersection of the first and second wiring lines, the memory cell including a variable resistance element. In a write operation from the memory cell, the control circuit repeats: a write pulse application operation that applies a write pulse voltage to the memory cell; and a verify read operation that applies a first voltage to the memory cell to determine whether the write operation has been completed or not. In a read operation from the memory cell, the control circuit applies a second voltage to the memory cell. The second voltage has a voltage value which is larger than that of the first voltage.

Embodiments of a semiconductor memory device and a method of manufacturing the same will be described below with reference to the drawings.

### First Embodiment

### Overall Configuration

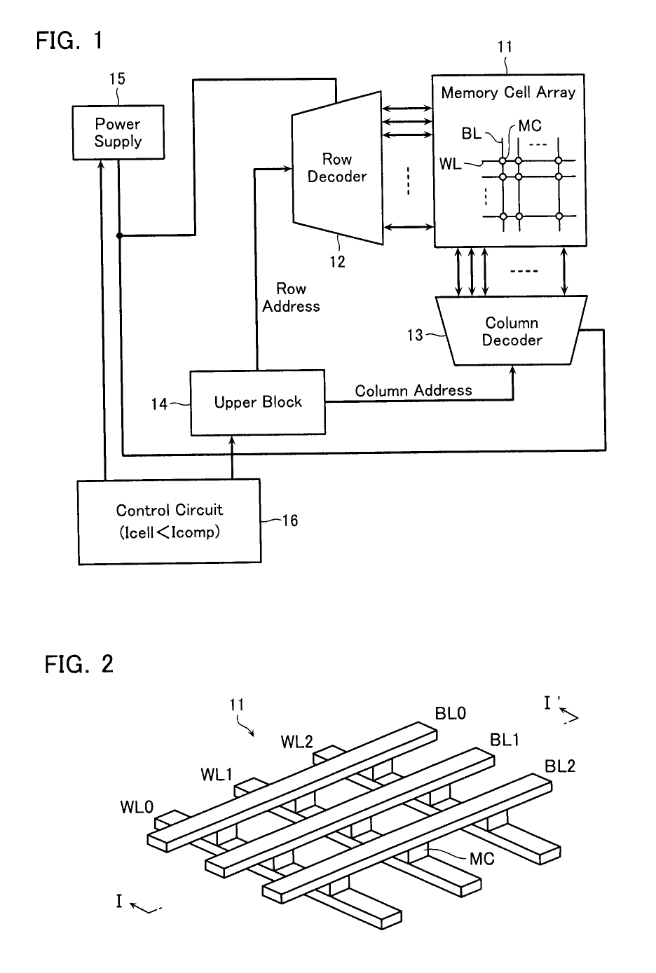

First, an overall configuration of a semiconductor memory device according to a first embodiment will be described. FIG. 1 is an example of a block diagram of the semiconductor memory device according to the first embodiment, and shows a plane type ReRAM device. As shown in FIG. 1, the semiconductor memory device includes a memory cell array 11, a row decoder 12, a column decoder 13, a higher block 14, a power supply 15, and a control circuit 16.

The memory cell array 11 includes: a plurality of word lines WL and bit lines BL that intersect each other; and a memory cell MC disposed at each of intersections of these word lines WL and bit lines BL. The row decoder 12 selects the word line WL during access (write/read). The column decoder 13 selects the bit line BL during access, and includes a driver that controls an access operation.

The higher block 14 selects the memory cell MC which will be an access target in the memory cell array 11. The higher block 14 provides a row address and a column address to the row decoder 12 and the column decoder 13, respectively. The power supply 15 generates certain combinations of voltages corresponding to each of operations of data erase/write/read, and supplies the certain combinations of voltages to the row decoder 12 and the column decoder 13.

The control circuit 16 performs control of the likes of sending an address to the higher block 14, and moreover performs control of the power supply 15, based on a command from external. In addition, the control circuit 16, while performing a write operation, such as a setting operation or a resetting operation, controls voltage values, and so on, such that a current (hereafter, called “cell current”) Icell flowing in the memory cell MC is smaller than a compliance current Icomp. Note that the control circuit 16 may comprise the likes of an ECC circuit that performs error detection/correction of data read from the memory cell array 11.

[Memory Cell Array and Memory Cell]

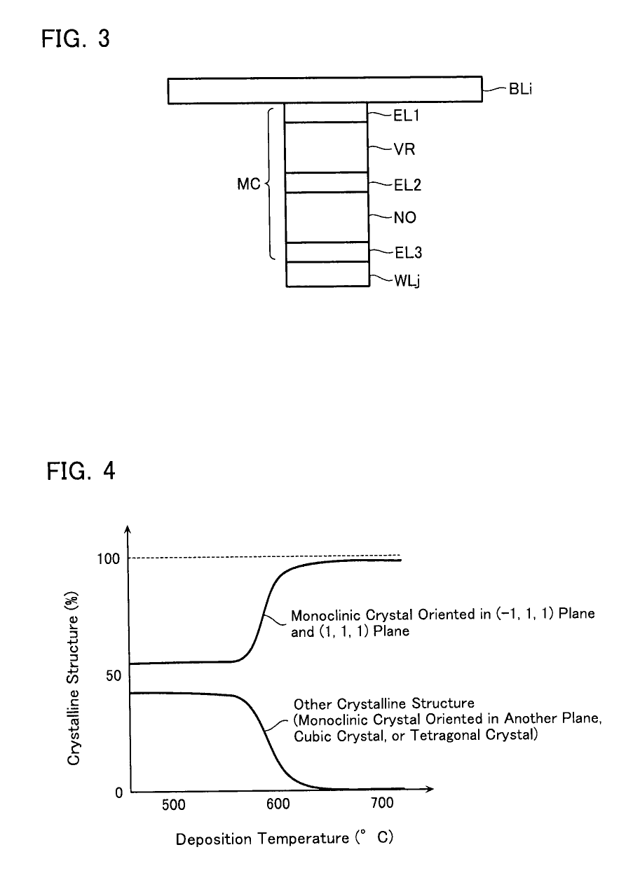

FIG. 2 is a perspective view of part of the memory cell array 11; and FIG. 3 is a cross-sectional view, taken along the I-I′ line in FIG. 2 and viewed in the direction of the arrows, of a single memory cell portion.

A plurality of word lines WL0 to WL2 acting as first wiring lines are arranged in parallel, a plurality of bit lines BL0 to BL2 acting as second wiring lines are arranged in parallel intersecting these word lines, and a memory cell MC is disposed at each of intersections of these word lines and bit lines, so as to be sandwiched by both wiring lines. The word line WL and the bit line BL are desirably of a material which is heat-resistant and has a low resistance value.

As shown in FIG. 3, the memory cell MC is a bipolar type memory cell configured from a series-connected circuit of a variable resistance element VR and a non-ohmic element NO. The variable resistance element VR nonvolatilely stores its resistance value as rewritable data. Moreover, the non-ohmic element NO is a non-ohmic element such as a diode or transistor, for example. Moreover, the bit line BL, variable resistance element VR, non-ohmic element NO, and word line WL are connected by electrodes EL1, EL2, and EL3 respectively interposed therebetween. These electrodes EL1, EL2, and EL3 function as a barrier metal and an adhesive layer. Note that it is also possible for another layer, such as a buffer layer, barrier metal layer, adhesive layer, and so on, to be inserted in the variable resistance element VR. Moreover, a unipolar type memory cell may be adopted as the memory cell MC.

[Variable Resistance Element VR]

Employed as the variable resistance element VR in the present embodiment is a hafnium oxide film having a crystalline structure of monoclinic crystal oriented in a specific plane.

A switching operation at a low current is required to achieve a large capacity ReRAM device. However, conventionally, there was a problem that due to noise, a read (Read) current ended up varying and reliability of data retention characteristics, endurance, and so on, ended up deteriorating.

As a result of pursuing diligent research to solve this problem, the inventors of the present invention discovered that by employing as the variable resistance element VR a hafnium oxide film of monoclinic crystal oriented in a (−1, 1, 1) plane and a (1, 1, 1) plane, noise can be suppressed and reliability of data retention characteristics, endurance, and so on, can be improved.

FIG. 4 shows a relationship between deposition temperature and crystalline structure in an ALD film-forming process of hafnium oxide (HfO₂).

Up to a deposition temperature being in the high 500° C. region, proportions of monoclinic crystal oriented in the (−1, 1, 1) plane and the (1, 1, 1) plane and other crystalline structure (monoclinic crystal oriented in another plane, cubic crystal, or tetragonal crystal) are both close to 50%, but just before 600° C., the proportion of monoclinic crystal oriented in the (−1, 1, 1) plane and the (1, 1, 1) plane rises sharply to become approximately 90% at 600° C., and when 620° C. is exceeded, becomes substantially close to 100%, whereby the proportion of other crystalline structure becomes under 3%.

Moreover, a component oriented in the (−1, 1, 1) plane and a component oriented in the (1, 1, 1) plane in the hafnium oxide monoclinic crystal are both essential, and a ratio (1, 1, 1)/(−1, 1, 1) of those components is preferably in a range of 0.6 to 1.4.

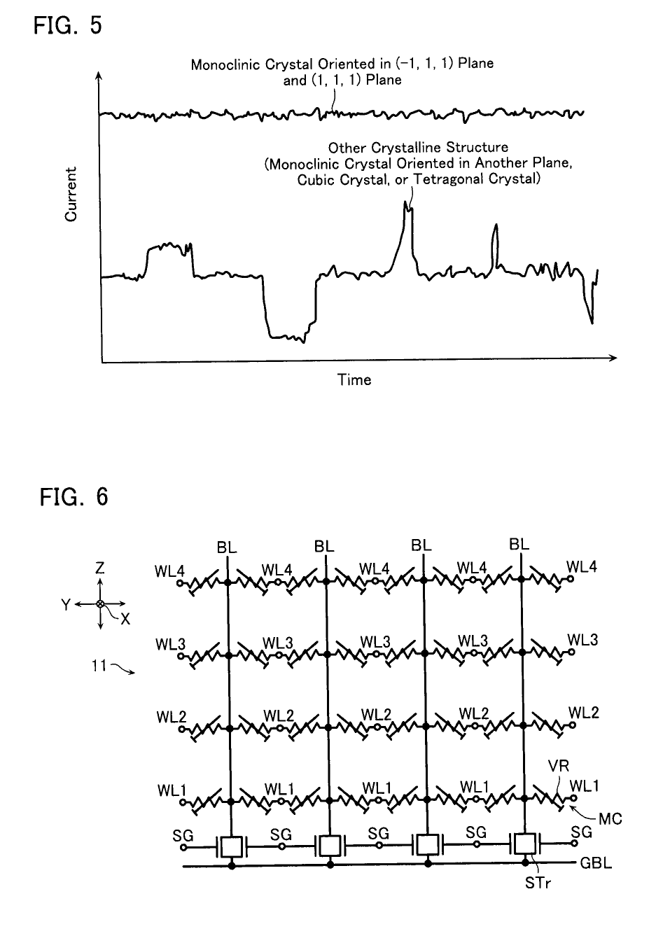

FIG. 5 shows a relationship between crystalline structure and current characteristics of hafnium oxide (HfO₂) employed in the variable resistance element VR. In same FIG. 5, an upper part is current characteristics of a ReRAM device employing a hafnium oxide film of monoclinic crystal oriented 90% or more in the (−1, 1, 1) plane and the (1, 1, 1) plane, and a lower part is current characteristics of a ReRAM device employing a hafnium oxide film having another crystalline structure.

It is found that in the ReRAM device employing as the variable resistance element VR a hafnium oxide film of monoclinic crystal oriented 90% or more in the (−1, 1, 1) plane and the (1, 1, 1) plane, the current value stays substantially constant even as time passes, whereas in the ReRAM employing a hafnium oxide film having another crystalline structure, the current value fluctuates significantly.

Moreover, the ReRAM device employing a hafnium oxide film of monoclinic crystal oriented 90% or more in the (−1, 1, 1) plane and the (1, 1, 1) plane showed good endurance (>1 k cycles) and good data retention characteristics (25° C., 10 years).

Although the reason why current characteristics are stable and good endurance and data retention characteristics were shown in this way in the ReRAM device employing a hafnium oxide film of monoclinic crystal oriented 90% or more in the (−1, 1, 1) plane and the (1, 1, 1) plane, is unclear, it is presumed to be due to the fact that since the hafnium oxide film of monoclinic crystal oriented in the (−1, 1, 1) plane and the (1, 1, 1) plane was close to a crystalline structure of hafnium oxide of stress-free bulk monoclinic crystal, effects of defects or impurities, and so on, that are a source of noise, were reduced, and inherent characteristics of hafnium oxide were displayed.

As is clear from the above, in the hafnium oxide film of the present embodiment, it is preferable for a proportion of monoclinic crystal oriented in the (−1, 1, 1) plane and the (1, 1, 1) plane to be raised to 90% or more, specifically, to a degree where a proportion of other crystalline structure is under 3%.

[Method of Manufacturing Hafnium Oxide Film of Monoclinic Crystal]

The hafnium oxide film of monoclinic crystal oriented in the (−1, 1, 1) plane and the (1, 1, 1) plane can be produced by a film-forming process by PVD (Physical Vapor Deposition) or ALD (Atomic Layer Deposition). In the ALD film-forming process, it is preferable to employ as a precursor an inorganic type hafnium (Hf)) precursor, for example, a halogenate of hafnium such as hafnium tetraiodide (HfI₄), hafnium tetrachloride (HfCl₄), hafnium tetrabromide (HfBr₄), or hafnium tetrafluoride (Hf F₄), and so on. If an organic type hafnium precursor other than the inorganic type hafnium precursor, for example, TDMAHf (Tetrakis-Dimethyl-Amino-Hafnium: Hf [N(CH₃)₂]₄) is employed, although hafnium oxide having a crystalline structure is obtained, it ends up having a variety of crystalline structures with a variety of orientations, and variation of current value due to noise ends up being large.

Moreover, in the ALD film-forming process, production can be performed by heating to a temperature of 600° C. to 750° C., preferably 620° C. to 700° C., and reacting with H₂O. The reason the temperature was set to 600° C. to 750° C. is because at under 600° C., as shown in FIG. 4, the proportion of the hafnium oxide film of monoclinic crystal oriented in the (−1, 1, 1) plane and the (1, 1, 1) plane ends up being under 90% and desired characteristics are not obtained, and if 750° C. is exceeded, film formation due to an ordinary ALD film-forming process is thought to be difficult.

### Second Embodiment

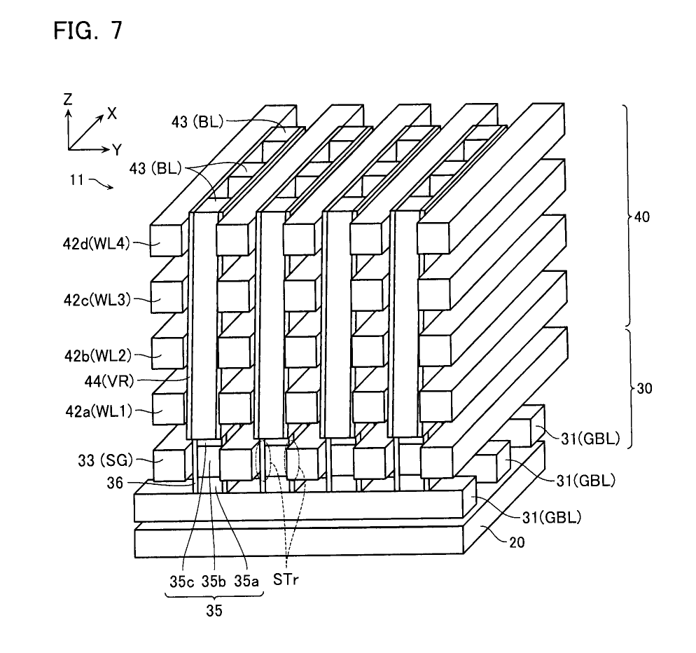

Next, a second embodiment will be described with reference to FIGS. 6 and 7. This embodiment is similar in configuration to the semiconductor memory device of the first embodiment shown in FIG. 1, except for a form of the memory cell array 11 being different. Specifically, the memory cell array of this second embodiment differs from that of the first embodiment being a VBL structure having a structure comprising a bit line extending in a perpendicular direction to a substrate. That is, the bit lines BL are arranged in plurality with a certain pitch in a direction parallel to the substrate, and extend having as their longer direction a direction perpendicular to the substrate. Furthermore, the word lines WL are arranged in plurality with a certain pitch in the direction perpendicular to the substrate, and extend having as their longer direction the direction parallel to the substrate.

FIG. 6 is an example of a circuit diagram of the memory cell array 11 according to the present embodiment. FIG. 7 is an example of a perspective view showing a stacked structure of the memory cell array 11. Moreover, the structure shown in FIG. 6 is provided repeatedly in an X direction. Note that in the description below, portions similar to those of the first embodiment are assigned with identical reference symbols to those assigned in the first embodiment, and description thereof will be omitted.

As shown in FIG. 6, the memory cell array 11 includes a select transistor STr, a global bit line GBL, and a select gate line SG, in addition to the above-mentioned word line WL, bit line BL, and memory cell MC.

As shown in FIGS. 6 and 7, word lines WL1 to WL4 are arranged with a certain pitch in a Z direction, and extend in the X direction. The bit lines BL are arranged in a matrix in the X direction and a Y direction, and extend in the Z direction. The memory cell MC is disposed at places where these word lines WL and bit lines BL intersect. Therefore, the memory cells MC are arranged in a three-dimensional matrix in the X, Y, and Z directions.

As shown in FIG. 6, the memory cell MC includes a variable resistance element VR.

As shown in FIG. 6, the select transistor STr is provided between the global bit line GBL and one end of the bit line BL. The global bit lines GBL are aligned with a certain pitch in the X direction, and extend in the Y direction. One global bit line GBL is commonly connected to one ends of the plurality of select transistors STr arranged in a line in the Y direction.

Moreover, gate electrodes disposed between two select transistors STr arranged adjacently in the Y direction may be commonly connected. The select gate lines SG are aligned with a certain pitch in the Y direction, and extend in the X direction. One select gate line SG is commonly connected to gates of the plurality of select transistors STr arranged in a line in the X direction. Note that it is also possible for the gate electrodes between two select transistors STr arranged adjacently in the Y direction to be isolated and the two select transistors STr to be each operated independently.

Next, the stacked structure of the memory cell array 11 according to the present embodiment will be described with reference to FIG. 7. FIG. 7 is a perspective view showing the stacked structure of the memory cell array 11. Note that in FIG. 7, an inter-layer insulating layer is omitted. Moreover, in FIG. 7, the word line WL is illustrated simplified.

As shown in FIG. 7, the memory cell array 11 includes a select transistor layer 30 and a memory layer 40. The select transistor layer 30 functions as the select transistor STr, and the memory layer 40 functions as the memory cell MC.

As shown in FIG. 7, the select transistor layer 30 includes a conductive layer 31 and a conductive layer 33. The conductive layer 31 functions as the global bit line GBL, and the conductive layer 33 functions as the select gate line SG and as a gate of the select transistor STr.

A plurality of the conductive layers 31 are each formed so as to extend having as their longer direction the Y direction horizontal to a substrate 20, and are arranged so as to be aligned with a certain pitch in the X direction parallel to the substrate 20. On the other hand, a plurality of the conductive layers 33 are formed so as to extend having the X direction as their longer direction and be aligned with a certain pitch in the Y direction.

In addition, as shown in FIG. 7, the select transistor layer 30 includes a columnar semiconductor layer 35 and a gate insulating layer 36. The columnar semiconductor layer 35 functions as a body (channel) of the select transistor STr, and the gate insulating layer 36 functions as a gate insulating film of the select transistor STr.

The columnar semiconductor layers 35 are disposed in a matrix in the X and Y directions, and extend in a column shape in the Z direction. Moreover, the columnar semiconductor layer 35 contacts an upper surface of the conductive layer 31, and contacts a side surface at an end portion in the Y direction of the conductive layer 33 via the gate insulating layer 36. Moreover, the columnar semiconductor layer 35 includes an N+ type semiconductor layer 35a, a P+ type semiconductor layer 35b, and an N+ type semiconductor layer 35c that are stacked.

The N+ type semiconductor layer 35a, the P+ type semiconductor layer 35b, and the N+ type semiconductor layer 35c each contact an inter-layer insulating layer not illustrated, at side surfaces at their end portions in the Y direction. The N+ type semiconductor layers 35a and 35c are configured by polysilicon implanted with an N+ type impurity, and the P+ type semiconductor layer 35b is configured by polysilicon implanted with a P+ type impurity. The gate insulating layer 36 is configured by, for example, silicon oxide (SiO₂).

As shown in FIG. 7, the memory layer 40 includes conductive layers 42a to 42d stacked in the Z direction. The conductive layers 42a to 42d function as the word lines WL1 to WL4.

The conductive layers 42a to 42d each include a pair of comb-tooth shapes facing each other in the X direction. The conductive layers 42a to 42d are configured by, for example, titanium nitride (TiN) or polysilicon.

Moreover, as shown in FIG. 7, the memory layer 40 includes a columnar conductive layer 43 and a variable resistance film (VR) 44. The columnar conductive layer 43 is configured by, for example, polysilicon. The columnar conductive layers 43 are disposed in a matrix in the X and Y directions and contact an upper surface of the columnar semiconductor layer 35, and extend having the Z direction as their longer direction. The columnar conductive layer 43 functions as the previously mentioned bit line BL.

[Variable Resistance Film (VR) 44]

Used in the variable resistance film (VR) 44 in the present embodiment is a hafnium oxide film of monoclinic crystal oriented 90% or more in the (−1, 1, 1) plane and the (1, 1, 1) plane.

The hafnium oxide film of monoclinic crystal oriented 90% or more in the (−1, 1, 1) plane and the (1, 1, 1) plane can be produced by an ALD film-forming process as described in the first embodiment. In the ALD film-forming process, manufacturing can be performed by employing an inorganic type hafnium precursor, for example, a halogenate of hafnium such as HfI₄, HfCl₄, HfBr₄, HfF₄, and so on, heating to a temperature of 600° C. to 750° C., preferably 620° C. to 700° C., and reacting with H₂O. It is sufficient for a film thickness of the variable resistance film 44 to be about several nm.

The VBL-ReRAM device employing as the variable resistance film 44 a hafnium oxide film of monoclinic crystal oriented 90% or more in the (−1, 1, 1) plane and the (1, 1, 1) plane showed good endurance (>1 k cycles) and good data retention characteristics (25° C., 10 years).

The variable resistance element VR described in the first embodiment and the variable resistance film (VR) 44 described in the second embodiment can be applied not only to the above-mentioned nonvolatile ReRAM device, but also to a volatile DRAM capacitor or, furthermore, to a semiconductor memory device and semiconductor device in general used for the purpose of suppressing noise.

[Others]

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a memory cell array; and
a control circuit that controls a voltage applied to the memory cell array,
the memory cell array comprising:
a first wiring line;
a second wiring line intersecting the first wiring line; and
a memory cell disposed at an intersection of the first and second wiring lines, the memory cell including a variable resistance element,
the variable resistance element being formed by a hafnium oxide crystalline film in which a proportion of a component oriented in a (−1, 1, 1) plane and a (1, 1, 1) plane is 90% or more.

2. The semiconductor memory device according to claim 1, wherein
the hafnium oxide crystalline film has a crystalline structure of monoclinic crystal.

3. The semiconductor memory device according to claim 2, wherein
in the hafnium oxide crystalline film, a proportion of crystalline structure other than the crystalline structure of monoclinic crystal oriented in the (−1, 1, 1) plane and the (1, 1, 1) plane is under 3%.

4. The semiconductor memory device according to claim 2, wherein
a ratio (1, 1, 1)/(−1, 1, 1) of a component oriented in the (1, 1, 1) plane to a component oriented in the (−1, 1, 1) plane is 0.6 to 1.4.

5. The semiconductor memory device according to claim 2, wherein
in the hafnium oxide crystalline film, a proportion of crystalline structure other than the crystalline structure of monoclinic crystal oriented in the (−1, 1, 1) plane and the (1, 1, 1) plane is under 3%, and a ratio (1, 1, 1)/(−1, 1, 1) of a component oriented in the (1, 1, 1) plane to a component oriented in the (−1, 1, 1) plane is 0.6 to 1.4.

6. A semiconductor memory device, comprising:
a memory cell array; and
a control circuit that controls a voltage applied to the memory cell array,
the memory cell array comprising:
a first wiring line extending in a first direction;
a second wiring line extending in a second direction, the second direction intersecting the first direction;
a memory cell disposed at an intersection of the first wiring line and the second wiring line, the memory cell including a variable resistance layer;
a third wiring line extending in a third direction, the third direction intersecting the first direction and the second direction; and
a select transistor connected between the first wiring line and the third wiring line, the select transistor switching electrical connection/non-connection of the first wiring line and the third wiring line,
the variable resistance layer being formed by a hafnium oxide crystalline film in which a proportion of a component oriented in a (−1, 1, 1) plane and a (1, 1, 1) plane is 90% or more.

7. The semiconductor memory device according to claim 6, wherein
the hafnium oxide crystalline film has a crystalline structure of monoclinic crystal.

8. The semiconductor memory device according to claim 7, wherein
in the hafnium oxide crystalline film, a proportion of crystalline structure other than the crystalline structure of monoclinic crystal oriented in the (−1, 1, 1) plane and the (1, 1, 1) plane is under 3%.

9. The semiconductor memory device according to claim 7, wherein
a ratio (1, 1, 1)/(−1, 1, 1) of a component oriented in the (1, 1, 1) plane to a component oriented in the (−1, 1, 1) plane is 0.6 to 1.4.

10. The semiconductor memory device according to claim 7, wherein
in the hafnium oxide crystalline film, a proportion of crystalline structure other than the crystalline structure of monoclinic crystal oriented in the (−1, 1, 1) plane and the (1, 1, 1) plane is under 3%, and a ratio (1, 1, 1)/(−1, 1, 1) of a component oriented in the (1, 1, 1) plane to a component oriented in the (−1, 1, 1) plane is 0.6 to 1.4.

11. A method of manufacturing a semiconductor memory device, the semiconductor memory device comprising: a memory cell array; and a control circuit that controls a voltage applied to the memory cell array, the memory cell array comprising: a first wiring line; a second wiring line intersecting the first wiring line; and a memory cell disposed at an intersection of the first and second wiring lines, the memory cell including a variable resistance element, the variable resistance element being formed by a hafnium oxide crystalline film in which a proportion of a component oriented in a (−1, 1, 1) plane and a (1, 1, 1) plane is 90% or more, the method comprising:
the hafnium oxide crystalline film being manufactured by a film-forming process by atomic layer deposition, employing an inorganic type hafnium precursor.

12. The method of manufacturing a semiconductor memory device according to claim 11, wherein
the hafnium oxide crystalline film has a crystalline structure of monoclinic crystal.

13. The method of manufacturing a semiconductor memory device according to claim 11, wherein
the inorganic type hafnium precursor is hafnium tetraiodide (HfI₄), hafnium tetrachloride (HfCl₄), hafnium tetrabromide (HfBr₄), or hafnium tetrafluoride (HfF₄).

14. The method of manufacturing a semiconductor memory device according to claim 13, wherein
the inorganic type hafnium precursor is hafnium tetraiodide (HfI₄).

15. The method of manufacturing a semiconductor memory device according to claim 11, wherein
the film-forming process by atomic layer deposition is implemented at a temperature of 600° C. to 750° C.

16. A method of manufacturing a semiconductor memory device, the semiconductor memory device comprising: a memory cell array; and a control circuit that controls a voltage applied to the memory cell array, the memory cell array comprising: a first wiring line extending in a first direction; a second wiring line extending in a second direction, the second direction intersecting the first direction; a memory cell disposed at an intersection of the first wiring line and the second wiring line, the memory cell including a variable resistance layer; a third wiring line extending in a third direction, the third direction intersecting the first direction and the second direction; and a select transistor connected between the first wiring line and the third wiring line, the select transistor switching electrical connection/non-connection of the first wiring line and the third wiring line, the variable resistance layer being formed by a hafnium oxide crystalline film in which a proportion of a component oriented in a (−1, 1, 1) plane and a (1, 1, 1) plane is 90% or more, the method comprising:
the hafnium oxide crystalline film being manufactured by a film-forming process by atomic layer deposition, employing an inorganic type hafnium precursor.

17. The method of manufacturing a semiconductor memory device according to claim 16, wherein
the hafnium oxide crystalline film has a crystalline structure of monoclinic crystal.

18. The method of manufacturing a semiconductor memory device according to claim 16, wherein
the inorganic type hafnium precursor is hafnium tetraiodide (HfI₄), hafnium tetrachloride (HfCl₄), hafnium tetrabromide (HfBr₄), or hafnium tetrafluoride (HfF₄).

19. The method of manufacturing a semiconductor memory device according to claim 18, wherein
the inorganic type hafnium precursor is hafnium tetraiodide (HfI₄).

20. The method of manufacturing a semiconductor memory device according to claim 16, wherein
the film-forming process by atomic layer deposition is implemented at a temperature of 600° C. to 750° C.
